(19) United States
(12) Patent Application Publication
(10) Pub. No.: US 2006/0286792 A1
(43) Pub. Date: Dec. 21, 2006

(54) Dual damascene process

(75) Inventors: Chia-Chi Chung, HsinCHu City (TW); H. Y. Tsai, HsinChu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/157,002

(22) Filed: Jun. 20, 2005

(51) Int. Cl. H01L 21/4763

(52) U.S. Cl. 438/622

(57) ABSTRACT

A dual damascene process for fabricating a semiconductor device. A dielectric layer is formed on a substrate, comprising at least one via opening therein. A trench opening is formed in the dielectric layer above the via opening and the via opening widened by in-situ etching.

### BACKGROUND

The present invention relates to semiconductor fabrication, and in particular to the fabrication of a semiconductor device by dual damascene process.

In the fabrication of semiconductor devices, the size of semiconductor devices has been continuously reduced in order to increase device density. Accordingly, multiple layers may be required for providing a multi-layered interconnect structure. A typical process for forming a multi-layered interconnect structure is a dual damascene process. In the dual damascene process, via openings are first anisotropically etched through an inter-metal dielectric (IMD) layer by conventional photolithography and etching. A second anisotropically etched opening referred to as a trench opening is then formed overlying one or more of the via openings by second photolithography and etching. The via openings and the trench opening together makeup the dual damascene structure which is subsequently filled with metal, for example, copper, followed by a CMP planarization to planarize the wafer process surface and prepare the process surface for formation of another overlying layer or level in a multi-layered semiconductor device.

After trench etching in the typical dual damascene process, however, several steps, such as ashing, wet cleaning, and stop layer etching may be performed one or more times in different chambers or chemical baths. As a result, cycle time is increased, reducing throughput and increasing fabrication cost.

Thus a need exists in the semiconductor technology to develop an improved dual damascene process to increase throughput and reduce fabrication cost.

### SUMMARY

Methods for fabricating a semiconductor device by dual damascene process are provided. An embodiment of a dual damascene process for fabricating a semiconductor device comprises forming a-dielectric layer on a substrate, comprising at least one via opening therein. A trench opening is formed in the dielectric layer above the via opening and the via opening widened by in-situ etching.

Another embodiment of a dual damascene process for fabricating a semiconductor device comprises forming a dielectric layer on a substrate, comprising at least one via opening therein. The via opening is filled with a sacrificial material. A trench opening is formed in the dielectric layer over the via opening by etching. The sacrificial material is removed by ashing using a process gas comprising carbon and fluorine, to simultaneously widen the via opening.

### BRIEF DESCRIPTION OF THE DRAWINGS

The invention will become more fully understood from the detailed description given hereinbelow and the accompanying drawings, given by way of illustration only and thus not intended to be limitative of the invention.

FIGS. 1a to 1e are cross-sections of an embodiment of a dual damascene process for fabricating a semiconductor device of the invention.

FIG. 2 is a curve diagram showing the relationship between cumulative probability (%) and contact resistance (Ω/□) of the interconnect.

### DESCRIPTION

As will be appreciated by persons skilled in the art from the discussion herein, the present invention has wide applicability to many manufacturers, factories and industries. For discussion purposes, the embodiments are made herein to semiconductor foundry manufacturing (i.e., wafer fabrication in an IC foundry). However, the present invention is not limited thereto.

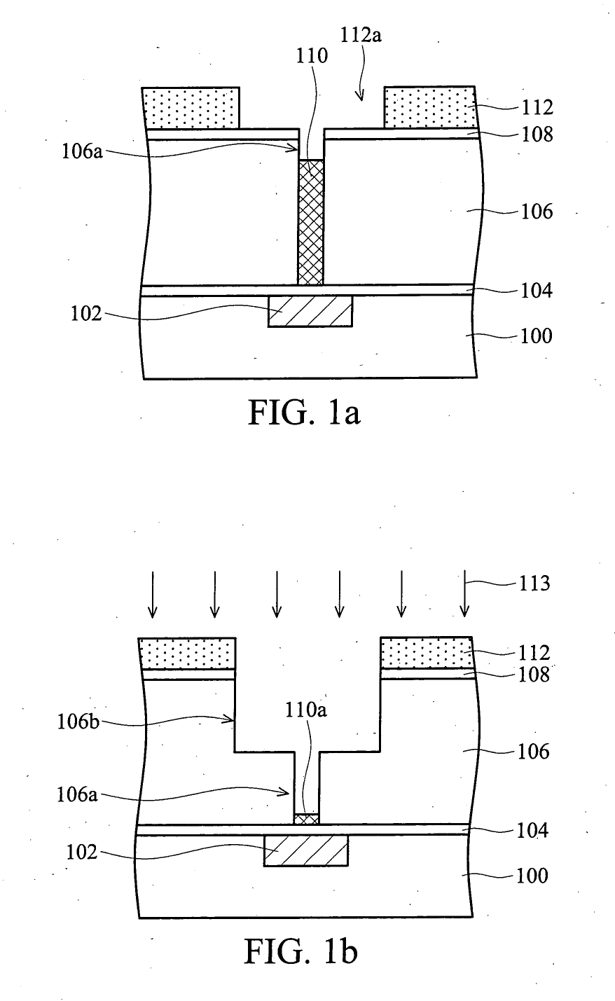

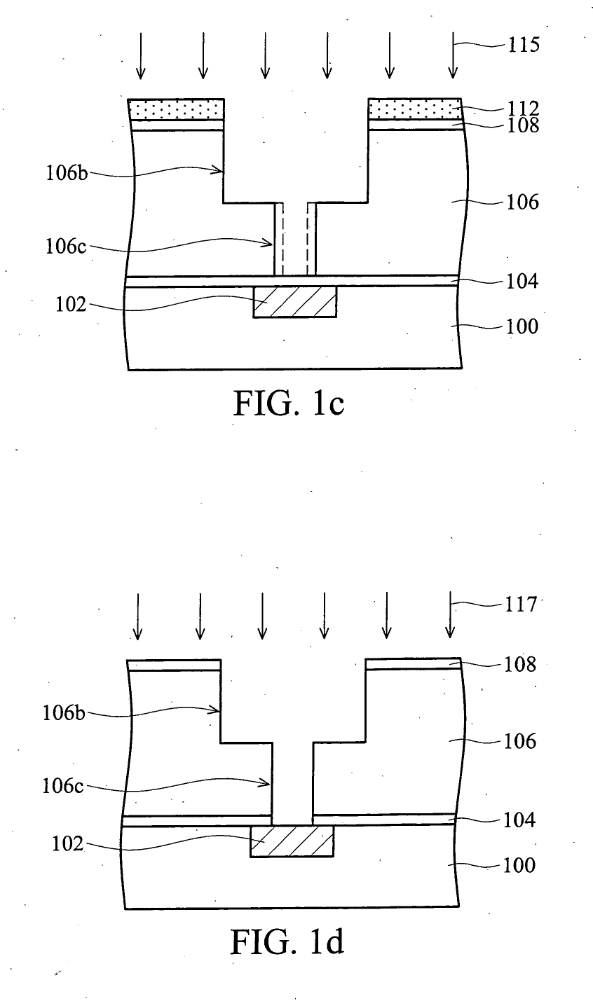

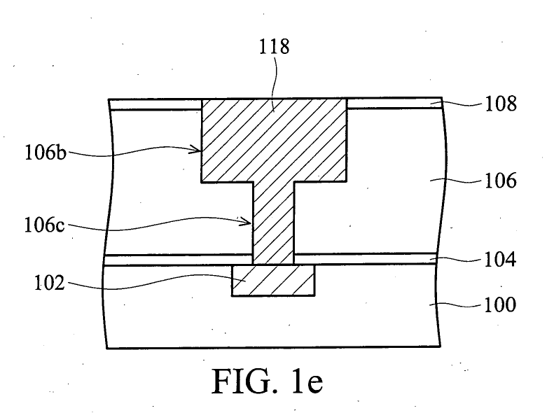

The invention relates to an improved damascene process. FIGS. 1a to 1e illustrate an embodiment of dual damascene process for fabricating a semiconductor device. In FIG. 1a, a substrate 100 is provided. The substrate 100, such as a silicon substrate or other semiconductor substrates, may contain a variety of elements, including, for example, transistors, resistors, and other semiconductor elements as are well known in the art. In order to simplify the diagram, a flat substrate is depicted. The substrate 100 may also contain a conductive region 102, such as a doping region of a transistor or an inlaid metal layer. In this embodiment, the conductive region 102 is the inlaid metal comprising copper, commonly used in the semiconductor industry for wiring the discrete semiconductor devices in and on the substrate.

A dielectric layer 106 is formed overlying the substrate 100, comprising at least one via opening 106a therein and over the inlaid metal 102. In this embodiment, the dielectric layer 106 is used as an interlayer dielectric (ILD) layer or an intermetal dielectric (IMD) layer. For example, the dielectric layer 106 may be, silicon dioxide, phosphosilicate glass (PSG), borophosphosilicate glass (BPSG). Preferably, the dielectric layer 106 comprises a low dielectric constant (k) material to achieve low RC time constant (resistance-capacitance), such as fluorosilicate glass (FSG) Moreover, the dielectric layer 106 can be formed by conventional deposition, such as plasma enhanced chemical vapor deposition (PECVD), low pressure CVD (LPCVD), atmospheric pressure CVD (APCVD), high-density plasma CVD (HDPCVD) or other suitable CVD. Additionally, a barrier or etching stop layer 104, such as a silicon nitride layer, can be optionally deposited on the substrate 100 by LPCVD using SiCl₂H₂ and NH₃ as process gases prior to deposition of dielectric layer 106. Moreover, an anti-reflective layer (ARL) 108 can be optionally deposited overlying the dielectric layer 106. The ARL 108 may be SiON formed by CVD using, for example, SiH₄, O₂, and N₂ as process gases.

The via opening 106a may be fully or partially filled with a sacrificial material 110, such as a bottom anti-reflective material. Next, a photoresist layer (not shown), such as photoresist, is coated on the ARL 108, and photolithography is subsequently performed on the photoresist layer to form a photoresist pattern layer 112 with at least one trench opening 112a over the via opening 106a for dual damascene structure definition.

Next, in FIG. 1b, conventional etching, such as reactive ion etching (RIE), is successively performed on the ARL 108 and the underlying dielectric layer 108 using the photoresist pattern layer 112 as an etch mask to transfer the trench opening 112a into the dielectric layer 108, forming a trench opening 106b in the dielectric layer 108 above the via opening 106a. At the same time, the sacrificial material 110 is also etched, leaving a portion of the sacrificial material 110a in the lower portion of the via opening 106a. In this embodiment, the ARL 108 is etched by a process gas comprising O₂, CF₄, C₄F₈, and a carrier gas, such as Ar, at a pressure of about 60 to 150 torr. The flow rates of O₂, CF₄, C₄F₈, and Ar are about 4 to 20 sccm, 10 to 100 sccm, 4 to 20 sccm, and 100 to 500 sccm, respectively. Moreover, the trench etching is performed by a process gas comprising O₂, CO, C₄F₈, and a carrier gas, such as Ar, at a pressure of about 50 to 200 torr. The flow rates of O₂, CO, C₄F₈, and Ar are about 3 to 18 sccm, 0 to 500 sccm, 2 to 20 sccm, and 100 to 1000 sccm, respectively. Thereafter, an in-situ ashing 113 may be performed to remove the remaining sacrificial material 110a in the lower portion of the via opening 106a. The ashing 113 may be performed by a process gas comprising oxygen or carbon, such as O₂ and CO, at a pressure of about 100 to 600 torr. The flow rates of O₂ and CO are about 500 to 3000 sccm and 0 to 500 sccm, respectively.

After trench etching or ashing 113, an in-situ etching 115 is performed by an etching gas comprising fluorine, such as C₄F₈, C₅F₈, or C₄F₆, to widen the via opening 106a by 1% to 10%, thereby forming a widened via opening 106c, as shown in FIG. 1c. Note that the in-situ etching. 115 must stop on the barrier layer 104, preventing the underlying interlaid metal 102 from damage. That is, the barrier layer 104 is not substantially penetrated after the via opening 106a is widened. The etching gas may also comprise oxygen or carbon, such as O₂ or CO. For example, the etching gas comprises O₂, CO, and C₄F₈, at a pressure of about 100 to 600 torr. The flow rates of O₂, CO, and C₄F₈,are about 500 to 3000 sccm, 0 to 500 sccm, and 4 to 20 sccm, respectively. The widened via opening 106c can reduce the contact resistance of the subsequent interconnect.

In another embodiment, the process gas for ashing the remaining sacrificial material 110a may further comprise fluorine and carbon, such as C₄F₈, thereby simultaneously widening the via opening 106a. That is, the ashing 113 can be combined with the via opening lateral enlargement 115. Also, the combined step can be in-situ performed after trench etching.

In FIG. 1d, a second in-situ ashing 117 may be optionally performed to remove the remaining photoresist pattern layer 112 overlying the dielectric layer 106 and clean the polymer (not shown) formed during trench etching and via opening lateral enlargement. The ashing 117 may be performed by a process gas comprising oxygen or carbon, such as O₂ and CO, at a pressure of about 100 to 600 torr. The flow rates of O₂ and CO are are about 500 to 3000 sccm and 0 to 500 sccm, respectively. Thereafter, the barrier layer 104 under the widened via opening 106c is removed by an etching gas comprising CF₄, at a pressure of about 60 to 200 torr. The flow rate of CF₄ is about 50 to 500 sccm.

Finally, in FIG. 1e, a conductive layer (not shown), such as copper, aluminum, or other well known interconnect material, is formed overlying the dielectric layer 106 and fills the trench and via openings 106b and 106c. The excess conductor layer over the ARL 108 is removed by an etching back process or, polishing, such as CMP, to leave a portion of conductive layer 118 in the damascene opening 108 to serve as an interconnect and complete the interconnect fabrication.

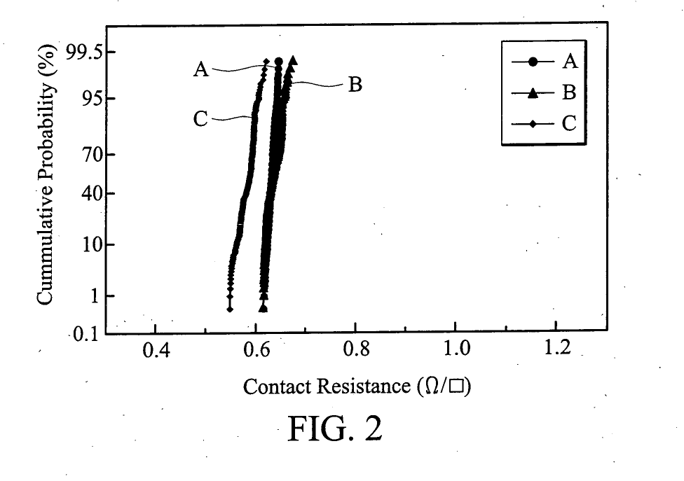

FIG. 2 is a curve diagram showing the relationship between cumulative probability (%) and contact resistance (Ω/□) of the interconnect, in which curve A indicates the interconnect formed by conventional dual damascene process without performing lateral enlargement of the via opening. Curves B and C indicate the interconnect formed by in-situ integrated dual damascene process with lateral enlargement of the via opening according to the invention performed for 15 and 20 seconds, respectively. As shown in FIG. 2, curve A has a contact resistance similar to curve B. Moreover, curve C has the lowest contact resistance compared with curves A and B. That is, the interconnect formed by the method of the invention can maintain its contact resistance compared with the conventional dual damascene process. Moreover, the contact resistance of the interconnect can be further reduced by performing the lateral enlargement of the via opening for a suitable time.

Accordingly, the interconnect formed by in-situ integrated dual damascene process of the invention can reduce fabrication cost and increase throughput. Moreover, the interconnect formed by performing the lateral enlargement of the via opening can further reduce its contact resistance, improving electrical performance of devices.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A dual damascene process for fabricating a semiconductor device, comprising:
forming a dielectric layer on a substrate, comprising at least one via opening-therein; and
forming a trench opening in the dielectric layer above the via opening and widening the via opening by in-situ etching.

2. The process of claim 1, further forming a sacrificial material in the via opening.

3. The process of claim 2, further removing the sacrificial material by an in-situ ashing using a process gas comprising oxygen or cabon.

4. The process of claim 1, wherein the via opening is widened by an etching gas comprising fluorine.

5. The process of claim 4, wherein the etching gas further comprises carbon or oxygen.

6. The process of claim 1, wherein the via opening is widened by an etching gas comprising C₄F₈, C₅F₈, or C₄F₆.

7. The process of claim 1, further forming a barrier layer between the dielectric layer and the substrate.

8. The process of claim 7, wherein the barrier layer is not substantially penetrated after widening the via opening.

9. The process of claim 7, further removing the barrier layer under the via opening by in-situ etching using CF₄ as an etching gas.

10. The process of claim 1, further performing an in-situ ashing on the dielectric layer using a process gas comprising oxygen or cabon after widening the via opening.

11. The process of claim 1, wherein the via opening is widened by 1% to 10%.

12. A dual damascene process for fabricating a semiconductor device, comprising:
forming a dielectric layer on a substrate, comprising at least one via opening therein;
filling the via opening with a sacrificial material;
forming a trench opening in the dielectric layer over the via opening by etching ; and
ashing the sacrificial material by a process gas comprising carbon and fluorine, to simultaneously widen the via opening.

13. The process of claim 12, wherein the process gas further comprises oxygen.

14. The process of claim 12, wherein the process gas comprises C₄F₈, C₅F₈, or C₄F₆.

15. The process of claim 12, further forming a barrier layer between the dielectric layer and the substrate.

16. The process of claim 15, wherein the barrier layer is not substantially penetrated after the via opening is widened.

17. The process of claim 15, further removing the barrier layer under the via opening by an in-situ etching using CF₄ as an etching gas after the via opening is widened.

18. The process of claim 12, wherein the via opening is widened by 1% to 10%.

19. The process of claim 12, wherein the ashing is in-situ performed on the sacrificial material.
